(19) United States
(12) Patent Application Publication
(10) Pub. No.: US 2001/0022359 A1
(43) Pub. Date: Sep. 20, 2001

(54) Gate isolated triple-well non-volatile cell

(76) Inventor: Sunil D. Mehta, San Jose, CA (US)

Correspondence Address: Larry E. Vierra, FLIESLER, DUBB, MEYER & LOVEJOY LLP, Four Embarcadero Center, Suite 400, San Francisco, CA, 94111-4156, US

(21) Appl. No.: 09/757,407

(22) Filed: Jan. 8, 2001

Related U.S. Application Data
(63) Continuation-in-part of application No. 09/369,904, filed on Aug. 6, 1999.

(51) Int. Cl. H01L 47/00

(52) U.S. Cl. 257/1

(57) ABSTRACT

A non-volatile memory cell comprises a first well region of a first conductivity type within a second well region of a second conductivity type in a substrate. At least one impurity region of an opposite conductivity type to said first conductivity type is formed in the first well as is a well tap region of said first conductivity type. An isolation gate is formed on the surface of the substrate between said at least one impurity region and said well tap region.

### BACKGROUND OF THE INVENTION

1. Field of the Invention

This invention relates generally to semiconductor devices, and more particularly, to an electrically erasable programmable read only memory (“EEPROM”) cell.

2. Description of Related Art

Production of semiconductor devices at feature sizes approaching 0.1 micron presents unique challenges. EEPROM devices are one of such semiconductor devices that must meet these challenges.

EEPROM devices are memory cells that store information and may be erased and reprogrammed electrically. An EEPROM cell is typically made up of three separate transistors, namely, a program or write transistor, a sense transistor and a read transistor. The EEPROM cell may be programmed, erased and read by removing or adding electrons to a floating gate. Thus, for example, the floating gate may be programmed by removing free electrons from the floating gate and thereby giving the floating gate a positive charge. When it is desired to erase an EEPROM cell, the floating gate is given a net negative charge by injecting electrons onto the floating gate. The read operation is performed by reading the state (current) of the sense transistor. In order to give the floating gate a positive charge (program) or negative charge (erase), electron tunneling, for example using the well-known Fowler-Nordheim tunneling technique, may be performed by applying the appropriate voltage potentials between the floating gate and a region, such as a drain region, of a transistor. Upon applying the appropriate voltage potentials, electron tunneling occurs through a tunnel oxide layer between the floating gate and the region.

As the feature sizes of EEPROM cells are scaled downward, prior art EEPROM cells exhibit certain scaleablity, cost and reliability limitations. First, the manufacturing process for a smaller EEPROM cell becomes more complex and, accordingly, manufacturing costs rise as transistor channel lengths are reduced. For example, as the channel length of a transistor of the EEPROM cell is scaled downward, the thickness of the gate oxide overlying the channel must also be reduced since the gate oxide thickness must be scaled with the channel length. In view of the fact that EEPROM cells already have a complex process to form multiple oxide thicknesses, additional oxide thicknesses for the transistors would add additional steps to further complicate the manufacturing process and thereby increase manufacturing costs.

Furthermore, in previous EEPROM cells, N conductivity type substrates were used which made operating the EEPROM cell more difficult. The difficulty arose from having to apply a bias to the N conductivity type substrate (difficult to perform) to prevent forward biasing of a P-well/N conductivity type substrate containing a tunneling transistor used to operate the EEPROM cell. The N conductivity type substrates are also not commonly used while P conductivity type substrates are predominately used in the semiconductor industry. A need therefore exists for an EEPROM cell using a P conductivity type substrate but with the selectivity of individually biased wells.

Prior art EEPROM cells such as that described in co-pending application Ser. No. 09/316,241, filed May 21, 1999, include so-called triple well cells, which allow for isolation of individual cells, and program and erase functions for the floating gate which occur across the entire channel. In application Ser. No. 09/316,241, an EEPROM cell is described that is programmed and erased by electron tunneling across an entire portion of separate transistor channels, rather than at an edge of a transistor region, by using a triple well structure (first N conductivity type well, second P conductivity type well and third source and drain regions). An example of this EEPROM cell is shown in FIG. 1 and has three transistors formed in a semiconductor substrate: a tunneling transistor 120, a sense transistor 130 and a read transistor 140.

The tunneling transistor 120 has a source 190, a drain 200, and a channel 230 between the source 190 and the drain 200. The tunneling transistor 120, the sense transistor 190 and the read transistor 200 are formed in a second well 180 that has a first conductivity type, e.g. a P conductivity type, that is the same as the conductivity type of the semiconductor substrate. The second well is formed in a first well 185 that has a conductivity type, e.g. an N conductivity type, that is opposite the conductivity type of the second well. The source 190 and the drain 200 have the second conductivity type. A tunnel oxide layer 240 is formed over the channel 230.

Between the tunneling transistor and the sense transistor is a program junction region 170, formed in the semiconductor substrate, and separated from the tunneling and the sense transistor by device isolation. The program junction region, having an N conductivity type, also has a program junction oxide layer overlying the program junction region.

A second type of triple well cell is illustrated in co-pending, commonly assigned patent application Ser. No. 09/239,072. FIG. 2 illustrates the configuration.

FIG. 2 shows a two-transistor EEPROM cell which is programmed and erased by electron tunneling across a tunneling channel in a P-well formed within an N-well in a P-type substrate. The EEPROM cell includes: a tunneling transistor 420 formed in a second well 422 (P-well) within a first well 421 (N-well) in the semiconductor substrate 410. A read transistor 450 is also formed within the semiconductor substrate 410. The read transistor 450 has a source 451, a drain 452, and a channel 453 between the source 451 and the drain 452. An oxide layer 454 and a read control gate 455 are formed over the channel 453. A program junction region 480, having the first conductivity type (N-type) is formed in the substrate 410 and separated from the tunneling transistor 420 by isolation 490. The tunneling transistor 420 is electrically connected 423 to the read transistor 450 through the drain 452. A floating gate 424 overlies a tunnel oxide layer 425 and a program junction oxide layer 426. Electron tunneling occurs through the tunnel oxide layer 425 upon incurrence of a sufficient voltage potential between the floating gate and a tunneling channel 427 to both program and erase the EEPROM cell.

The EEPROM cell of FIG. 2 provides electron tunneling through the tunnel oxide layer across the entire portion of the tunneling channel 427. The EEPROM cell further has reduced thicknesses for the tunnel oxide layer and the program junction oxide layer to improve scaleablity and reduce operating voltages of the EEPROM cell of the present invention.

Electron tunneling in either the cell of FIG. 1 or FIG. 2 through the tunnel oxide layer 425 overlying channel 427 occurs upon incurrence of a sufficient voltage potential between the floating gate 424 and the tunneling channel 427.

A well structure which would allow performance and size optimization of EEPROM cells such as those shown in FIG. 2 would have broad-ranging applications, even beyond those uses particular to Fowler-Nordheim cells or EEPROM devices.

### SUMMARY OF THE INVENTION

The invention, roughly described, comprises a non-volatile memory cell formed in a substrate. The substrate includes a surface and a first well region of a first conductivity type is formed in the substrate. At least one impurity region of an opposite conductivity type to said first conductivity type is formed in the first well. A well tap region of said first conductivity type is formed in the well. An isolation gate is formed on the surface of the substrate between said at least one impurity region and said well tap region. In further embodiments, said isolation gate may comprise a polysilicon gate having a width of about 0.15 μm to 0.5 μm that is coupled to ground.

The invention provides a non-volatile, triple well structure which utilizes less substrate area while allowing individual well isolation of non-volatile structures.

### BRIEF DESCRIPTION OF THE DRAWINGS

The invention will be described with respect to the particular embodiments thereof. Other objects, features, and advantages of the invention will become apparent with reference to the specification and drawings in which:

FIG. 1 is a cross-sectional view of a prior art embodiment of the EEPROM cell shown in co-pending application Ser. No. 09/316,241.]

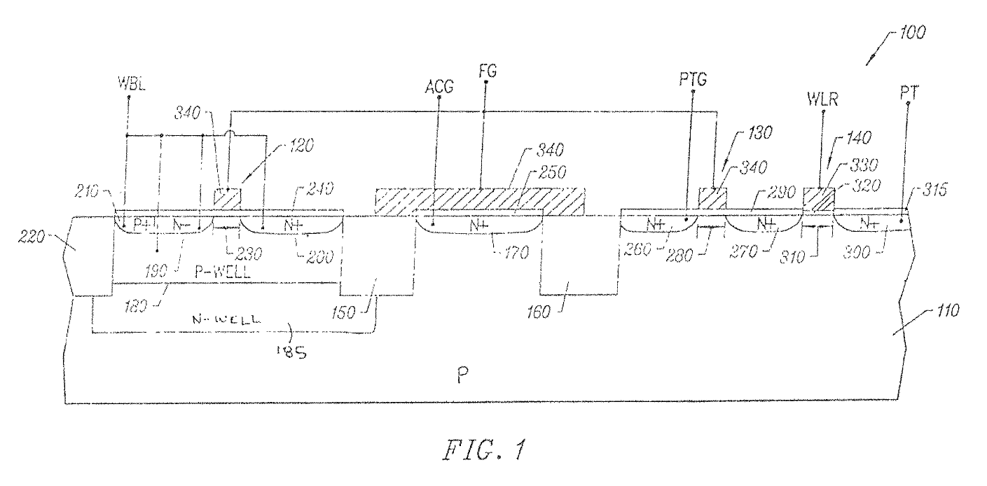

FIG. 2 is a cross-sectional view of a prior art embodiment of the EEPROM cell shown in co-pending application Ser. No. 09/239,072.

FIG. 3 is a circuit diagram view of an embodiment of the EEPROM cell of the present invention.

FIG. 4 is a cross-sectional view of an embodiment of the EEPROM cell of the present invention.

FIG. 5 is a cross-sectional view of the non-volatile transistor in the embodiment of the EEPROM cell of the present invention.

### DETAILED DESCRIPTION

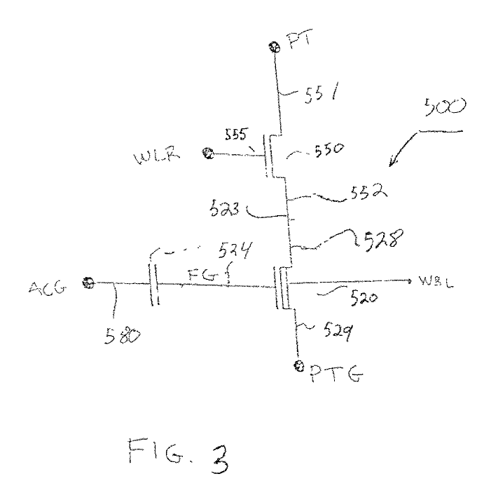

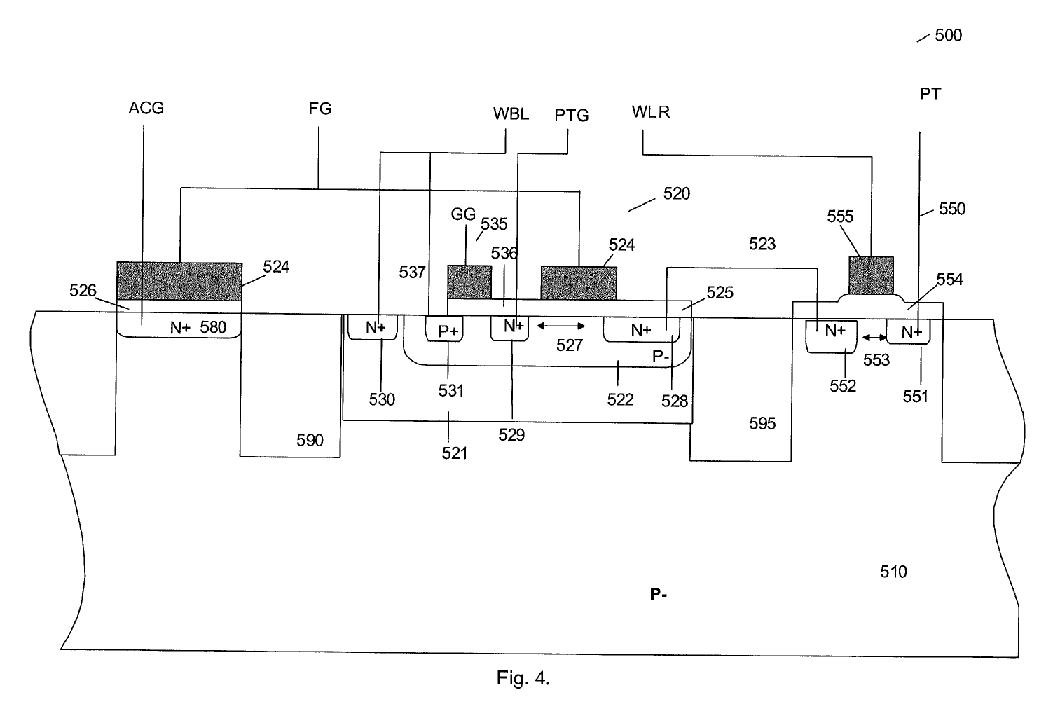

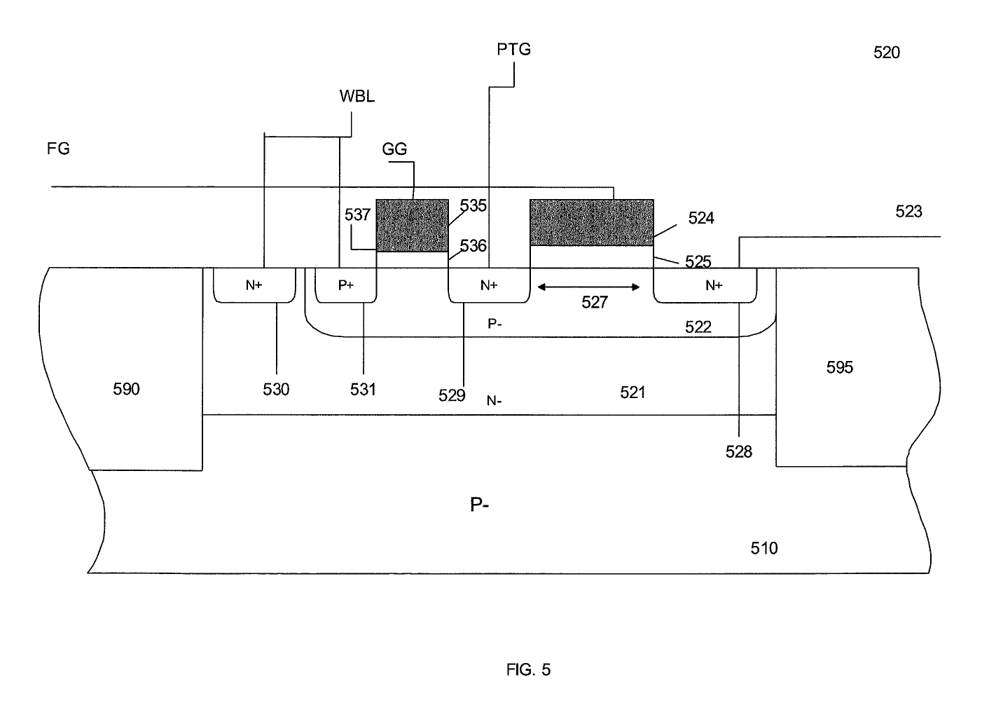

FIG. 4 is a cross-sectional view of one embodiment of the EEPROM cell of the present invention. FIG. 5 is a cross-sectional view of a portion of the tunneling transistor of one embodiment of the EEPROM cell of the present invention. For simplicity, the read transistor 550 of the embodiment of a cell 500, which is also represented schematically in FIG. 3, is not shown in FIG. 5.

As shown in FIG. 5, the embodiment of the EEPROM cell 500 is formed on a semiconductor substrate 510, for example a silicon substrate, and has a first conductivity type, e.g. a P conductivity type. In one embodiment, the semiconductor substrate is a bulk substrate being entirely formed of a P conductivity type material. In another embodiment, the semiconductor substrate is formed of a P conductivity type material having an epitaxial layer on a top surface where the epitaxial layer is formed of a P conductivity type material. The P and N conductivity type materials (known as dopants) are those materials commonly known in the art that alter the conductivity of a semiconductor material by contributing either a hole (P type) or an electron (N type) to the conduction process. For silicon substrates, the dopants are generally found in Groups III and V of the well-known chemical periodic table. In alternative embodiments, the semiconductor substrate 410 may be alternative silicon materials well-known in the semiconductor industry such as germanium, germanium/silicon, gallium arsenide, polysilicon, silicon on insulator or the like. It is noted that P conductivity type semiconductor substrates are more widely prevalent than N conductivity type substrates making the EEPROM cell 500 more widely acceptable in the semiconductor industry.

The tunneling transistor 520 may be used in an EEPROM cell 500 (FIGS. 3 and 4, respectively), of which transistor 520 is a part. The cell 500 is shown schematically in FIG. 3 and in cross-section in FIG. 4.

FIG. 3 shows the two transistors of cell 500: the tunneling transistor 520 and the read transistor 550. The source of the tunneling transistor 529 is shown to be electrically connected to PTG and the floating gate 524 of the tunneling transistor is capacitively coupled through the program junction oxide layer 526 to ACG.

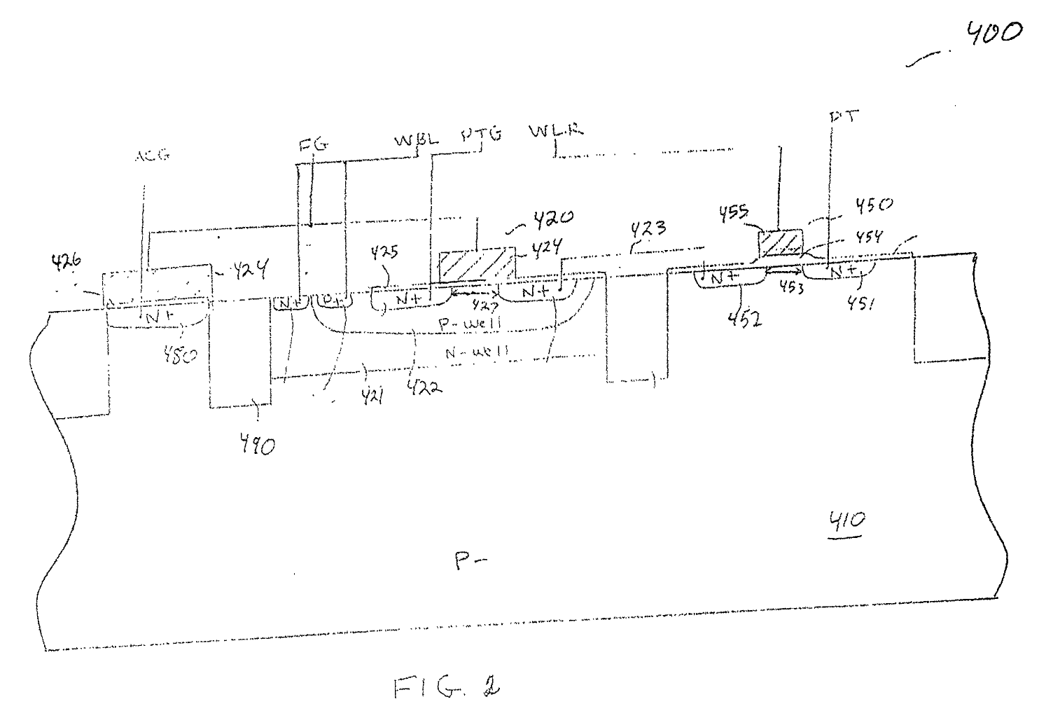

The read transistor and program junction region (ACG) have the same cross-sectional configuration as that shown in FIG. 2. As shown in FIG. 5, a program junction region (ACG) 580 and read transistor are also formed in the semiconductor substrate 510 and are electrically separated from the tunneling transistor 520 by an isolations 590 and 595, respectively. The program junction region 580 has a second conductivity type, such as an N+ conductivity type, and is a highly doped N+ region similar to that shown in FIG. 2. The read transistor has an oxide layer 554 and a read control gate 555 are formed over the channel 453. The read control gate is electrically connected to WLR.

As shown in FIG. 4, the tunneling transistor 520 has a first active region 528 and a second active region 529, all formed within a second well 522. The second well 522 has a first conductivity type, e.g. a P conductivity type. The second well 522 is formed within a first well 521 having a second conductivity type that is opposite the first conductivity type, e.g. an N type conductivity. It is understood that while the embodiment of FIG. 4 depicts the first well 521 as having an N conductivity type and the second well 522 as having a P conductivity type, alternative embodiments may have differing conductivity types as along as the conductivity types of the first and second wells are opposite conductivity types and the EEPROM cell 500 is able to function at the programming and erasing voltages provided below.

A P+ region 531, having a P conductivity type, is formed, using conventional implant techniques, in the second well 522 in order to provide electrical connection between a Word Bit Line (WBL) to the second well 522. The first well 521 is also electrically connected to WBL to prevent forward biasing of the junction between the first well 521 and the second well 522. The electrical connection between the first well 521 and WBL is established via the N+ region 530, which is formed in a similar fashion to the P+ region 531. In alternative embodiments (not shown), the first well 521 is common to a row, column or array of EEPROM cells and is maintained at a high voltage to prevent the forward biasing of the p-n junction between the first well 521 and the second well 522.

The tunneling source 529 and tunneling drain 528 have the N conductivity type. The transistor 520 is therefore an NMOS transistor in this embodiment. By using a NMOS transistor in a P-well (second well 522), the entire tunneling channel 527 may be used to perform electron tunneling that has certain benefits as described below. This is because the second well 522, in conjunction with the tunneling source 529 and tunneling drain 528, may be used to create the appropriate potential across the entire tunneling channel 527 to allow the entire tunneling channel 527 to be used for electron tunneling.

In accordance with the present invention, the transistor 520 includes a novel well and well contact structure which improves performance of the tunneling transistor by isolating the P+ region 531 using a narrow, grounded gate structure 535. The cells described herein derive many advantages from the use of the separate well 522 within the first well 521. Generally, these double well structures provide layout issues for device designers since the double wells take up a good deal of surface area for the cell. Hence, it would be desirable to reduce the area occupied by the cell by reducing the required thickness of the well regions and by allowing the double well structures to be isolated by isolation regions.

If the well under the tunneling transistor is deeper than the isolation, large well-to-well spacing is required to construct cells. In accordance with the invention, the grounded gate 535 may comprise a layer of polysilicon 537 on an oxide layer 536, with the oxide layer formed at the same time that the tunnel oxide layer 525 (and other oxide layers) are formed. The use of the grounded gate 535 isolates the P+ region 531, which allows for individually selectable cells in a smaller footprint.

It will be recognized that the scale of the gate region 535 can be quite small in comparison to the floating gate 524. For example, where the channel length in the floating gate region (tunneling channel 527), the length between region 528 and region 529 is about 0.3 μm to 0.7 μm, the distance between region 529 and region 531 may be about 0.15 μm to 0.5 μm. In addition, formation of the grounded gate structure allows self aligned formation of regions 528, 529 and 531. Formation of the gate structure 535 may be implemented by any number of standard techniques for forming the underlying oxide layer, depositing polysilicon and etching the polysilicon to form the grounded gate structure 535. In all aspects of programming and erase, the grounded state of the gate 535 isolates the P+ contact region 531.

Like the cell shown in FIG. 2, the transistors of the EEPROM cell 500 are electrically connected to certain electrical lines and gates in order to operate and control the functions of the EEPROM cell 500. As shown in FIGS. 3 and 4, a Word Bit Line (WBL) is electrically connected to the first and second wells, 521 and 522, via the respective P+ and N+ contact regions 530 and 531. The WBL is electrically connected to the second well 522 so that the entire portion of the tunneling channel 527 may be used to erase and program the EEPROM cell 500. The first well 521 isolates well 522 from the substrate, allowing cells to be individually erased. The first well 521 is connected to the WBL in order to prevent forward biasing of the p-n junction between the first and second wells.

It should be understood that electrical connecting includes any manner of transmitting charge between the two items being connected. FIG. 4 illustrates the connections for cell 500. One of average skill in the art will recognize the corresponding connections for cell 500 shown in cell 400, as discussed below.

The method of manufacturing the EEPROM cell 500 includes standard deposition and etching techniques. For example, in one embodiment, the EEPROM cell 500 is formed as follows. The semiconductor substrate 510, which may have an epitaxial layer (not shown) on the top surface of the semiconductor substrate 510, is patterned and etched (using conventional techniques) to form deep trenches for device isolation regions 590 and 595 of FIG. 4. The first well 521 is then formed by implanting the appropriate conductivity type, e.g. N conductivity type, into the semiconductor substrate 510. The second well 522 is then formed in the first well 521 by implanting the appropriate conductivity type, e.g. a P conductivity type, into the first well 521.

The tunnel oxide layer 525, as well as oxide layers for the program junction region, and read transistor are then formed using common deposition or oxide growing techniques. After these oxide layers have been formed, the gates for the transistors, including the floating gate 524 and grounded gate 537, are formed and patterned using conventional techniques. The gates are typically formed of a conducting material, e.g. a polycrystalline silicon material. Next, the source and drain implants are formed for each transistor. It is understood that a plurality of EEPROM cells are manufactured into an EEPROM device in order to store a multitude of information. The EEPROM cell further includes numerous metallization layers (not shown) overlying the cell 500 to electrically connect the cell 500 to other cells and other devices in an EEPROM device, as well as passivation layers (not shown) to protect the cell 500.

The three operations of the EEPROM cell 500 are program, erase and read. The various voltages applied to the EEPROM cell to perform these operations are shown in Table 1 below.

TABLE 1

| | WBL | ACG | PTG | WLR | PT |
|---|---|---|---|---|---|
| Program (bulk) | ground | Vₚₚ | ground | V_{cc} | ground |
| Erase (bit) - selected cell | Vₚₚ | ground | Vₚₚ/2 | Vₚₚ + | Vₚₚ |
| Erase - unselected row of cells | Vₚₚ | Vₚₚ/2 | Vₚₚ/2 | Vₚₚ + | Vₚₚ/2 |
| Erase - unselected column of cells | ground | ground | Vₚₚ/2 | ground | Vₚₚ |
| Read (Depletion Mode) | ground | ground | ground | V_{cc} | V_{cc}/2 |
| Read (Enhancement Mode) | ground | V_{cc} | ground | V_{cc} | V_{cc}/2 |

The program operation of the EEPROM cell 500 is defined, for this embodiment, as providing a net negative charge on the floating gate FG. For the erase operation, a positive charge is provided on the floating gate FG. It is understood, however, that alternative embodiments may deviate from this definition, yet fall within the scope of the present invention as claimed below. That is, the erase operation may put a negative charge on the floating gate FG as long as the program operation puts the opposite charge (positive) on the erase operation. Thus, alternative embodiments may create potentials between the floating gate FG and the appropriate channels that provide a net negative charge on the floating gate FG to erase the EEPROM cell 400a and provide a positive charge on the floating gate 524 to program the EEPROM cell 500.

The method of moving electrons to the floating gate 524 is commonly known to those skilled in the art as Fowler-Nordheim tunneling. In general, this process has electrons tunnel through a barrier, for example a thin oxide layer, in the presence of a high electric field. Like the cell shown in FIG. 2, the present invention provides for electron tunneling across a transistor channel. Further, the entire portion of the channel is used for electron tunneling rather than only an edge of a region as has been previously done since an NMOS transistor in a P-well (second well 522) is used for the tunneling transistor 520. Still further, the addition of the first well 521 prevents forward biasing of a p-n junction that would occur if the first well 521 was not used and a substrate having a second conductivity type, e.g. N conductivity type was used. By using the first well 521 and a substrate 510 with a second conductivity type, e.g. P conductivity type, the substrate 510 does not need to be biased in order to prevent forward biasing of the p-n junction.

The EEPROM cell 500 formed with double well-tunneling transistor 520 has numerous advantages over previous EEPROM cells. The electron tunneling is performed through a transistor channel rather than a source/drain region. By using an NMOS transistor in a P well 522 for the tunneling transistor 520, the entire tunneling channel 527 may be used to perform electron tunneling. By tunneling across a channel, the reliability of the EEPROM cell is increased since a larger oxide, rather than a small oxide window, is used for programing and erasing operations.

The EEPROM cell 500 is read by determining the state of read transistor 550. In one embodiment, the read transistor is a depletion mode transistor in which WBL, ACG, and PTG are grounded, WLR is set to V_{cc}, for example 1.8 volts, and PT is set to V_{T}(V_{cc}/2), for example 0.7 volts. If the read transistor 550 is an enhancement mode transistor, WBL and PTG are grounded, ACG and WLR are set to V_{cc}, and PT is set to V_{T}(V_{cc}/2). Thus, the state of read transistor 550 is a logical 1 during erase since a positive charge is on floating gate FG while a logical 0 is the state of sense transistor 140 during program.

It should be further recognized that the subject matter of this invention has broader applicability than that set forth in the exemplary embodiment herein. For example, the isolation aspects of the isolation gate have applicability to any structure where there is a desire to bias an isolated well region in a substrate without taking a premium of chip area for well to well spacing. For example, the invention may be used with avalanche programming cells, such as that described in co-pending application Ser. No. 09/220,201 filed Dec. 23, 1998, commonly assigned, Inventors Stewart G. Logie, Sunil D. Mehta, and Steven J. Fong, hereby incorporated by reference.

The EEPROM cell of the present invention has been described in connection with the embodiments disclosed herein. Although an embodiment of the present invention has been shown and described in detail, along with variances thereof, many other varied embodiments that incorporate the teachings of the invention may be easily constructed by those skilled in the art that may fall within the scope of the present invention as claimed below.

What is claimed is:

1. A non-volatile memory cell formed in a substrate, the substrate having a surface, comprising:
a first well region of a first conductivity type in the substrate;
at least one impurity region of an opposite conductivity type to said first conductivity type in the first well;
a well tap region of said first conductivity type in the well; and
an isolation gate formed on the surface of the substrate between said at least one impurity region and said well tap region.

2. The non-volatile memory cell of claim 1 wherein said first well is formed in a second well, the second well having said opposite conductivity type.

3. The non-volatile memory cell of claim 1 further including a floating gate positioned adjacent said at least one impurity region.

4. The non-volatile memory cell of claim 1 wherein said isolation gate is coupled to ground.

5. The non-volatile memory cell of claim 1 wherein said first conductivity type is a p-type, and said opposite conductivity type is an n-type conductivity.

6. The non-volatile memory cell of claim 1 wherein said isolation gate comprises a polysilicon gate having a width of about 0.15 to 0.5 microns which is coupled to ground.

7. A non-volatile memory structure, comprising:
a substrate;
a first well formed in the substrate;
a second well formed in the first well in the substrate;
a floating gate overlying a portion of the surface of the substrate; and
an isolation gate overlying another portion of the surface of the substrate.

8. The non-volatile memory structure of claim 7 further including a first impurity region having a first impurity type and a second impurity region of a second impurity type, the isolation gate positioned between the first and second impurity regions.

9. The non-volatile memory structure of claim 8 wherein said first conductivity type is an n-type, and said second conductivity type is a p-type conductivity.

10. The non-volatile memory structure of claim 8 wherein said first conductivity type is a p-type, and said second conductivity type is a n-type conductivity.

11. The non-volatile memory structure of claim 8 further including a third impurity region of said first impurity type, wherein said floating gate is positioned between said first and third impurity regions.

12. The non-volatile memory structure of claim 7 wherein said isolation gate comprises a polysilicon gate having a width of about 0.15 to 0.5 microns which is coupled to ground.

13. The non-volatile memory structure of claim 7 further including a read transistor and a pro gram junction region, the floating gate capacitively coupled to said program junction region.

14. A non-volatile memory cell, comprising:
a semiconductor substrate having a first conductivity type;
a non-volatile transistor, formed in the substrate, comprising:
a floating gate;
a first well region formed in the substrate and having an opposite conductivity type to said substrate;
a second well region formed in the first well region and having the same conductivity type as said substrate;
first, second and third impurity regions in said second well region;
an isolation gate separating said first and second impurity regions.

15. The non-volatile memory cell of claim 14 wherein said isolation gate is coupled to ground.

16. The non-volatile memory cell of claim 14 further including a program junction region capacitively coupled to the floating gate.

17. The non-volatile memory cell of claim 16 further including a read transistor coupled to the non-volatile transistor.
